(19) United States
(12) Patent Application Publication
(10) Pub. No.: US 2019/0090376 A1
(43) Pub. Date: Mar. 21, 2019

(54) APPARATUS, SYSTEM, AND METHOD FOR RESISTING SHOCK TO A DATA-CENTER RACK

(71) Applicant: Facebook, Inc., Menlo Park, CA (US)

(72) Inventors: Chuankeat Kho, San Jose, CA (US); Jason David Adrian, San Jose, CA (US)

(21) Appl. No.: 15/708,075

(22) Filed: Sep. 18, 2017

(51) Int. Cl. H05K 7/14; H05K 7/18

(52) U.S. Cl. CPC H05K 7/1495; H05K 7/1489; H05K 7/18

(57) ABSTRACT

A rack latch apparatus may include a rigid rack lock latch that includes a distal end coupled to a chassis and a protrusion dimensioned to lock the chassis in a rack. The apparatus may also include at least one spring standoff that couples the distal end of the rack lock latch to the chassis such that a tension maintains a locked position of the rack lock latch during a shock event. Various other apparatuses, systems, and methods are also disclosed.

### BACKGROUND

Large data centers may have rooms that contain multiple specialized racks to hold various types of computing equipment. In addition, each of these racks may hold multiple pieces of computing hardware that provide storage and computing power for organizations or individuals. For example, a data center may contain racks of hard drives and servers that process data and transmit information over a network. Occasionally, these data-center racks may be subjected to shocks or accidental forces. For example, racks may fall or be bumped during transportation or due to natural phenomena. These shocks to the system may cause damages to electronics housed by the racks or cause shifts that prevent normal functioning.

Traditionally, data-center racks may be protected by materials that provide a cushioning effect and/or attempt to maintain a fixed position of the hardware in a rack. For example, additional padding around hardware components may absorb part of the force. In another example, mechanisms composed of flexible materials may permit minor movement while preventing components from shifting beyond a set tolerance. However, large shocks may be difficult to sufficiently absorb, and flexible mechanisms may distort over time. In these instances, the hardware in the racks may suffer crucial loss and/or may eventually dislodge from the proper positions. Therefore, data-center racks may need improved methods for resisting shock and securing hardware to avoid permanent shifts.

### SUMMARY

As will be described in greater detail below, the instant disclosure describes various apparatuses, systems, and methods for resisting shock to a data-center rack by locking a chassis in place with a rack latch that may readjust the position of the chassis in response to a shock. In one example, a rack latch apparatus may include a rigid rack lock latch that includes a distal end coupled to a chassis and a protrusion dimensioned to lock the chassis in a rack. The rack latch apparatus may also include one or more spring standoffs that couple the distal end of the rack lock latch to the chassis such that a tension maintains a locked position of the rack lock latch during a shock event.

In some embodiments, the distal end of the rack lock latch may be coupled to a wall of the chassis such that the rack lock latch exerts a force outward toward the rack. In one embodiment, the protrusion may be dimensioned to fit an indentation in a side of the rack to lock the chassis in a position.

In some examples, a proximal end of the rack lock latch may extend beyond the chassis such that a force applied horizontally to the proximal end of the rack lock latch unlocks the rack lock latch. In these examples, the force applied horizontally to the proximal end of the rack lock latch may compress a spring standoff.

In one embodiment, the spring standoff may include a bar, an anchor coupled to a distal end of the bar, a cap coupled to a proximal end of the bar, a spacer fitted around the bar, and a compression spring dimensioned to maintain the tension separating the cap and the spacer. In this embodiment, the bar may be inserted through a wall of the chassis and the distal end of the rack lock latch such that the wall of the chassis separates the anchor and the rack lock latch. Additionally, the spacer may exert a force on the rack lock latch toward the wall of the chassis.

According to various embodiments, a corresponding data-center rack system may include a rack dimensioned to hold computer hardware. The data-center rack system may also include one or more chassis coupled to the rack and dimensioned to hold a drawer. Furthermore, the data-center rack system may include one or more right rack latches coupled to a right wall of a chassis to maintain a position of the chassis in the rack during a shock event and one or more left rack latches coupled to a left wall of the chassis to maintain the position of the chassis in the rack during the shock event. In one example, the drawer may be dimensioned to slide in the chassis such that the drawer extends away from the rack to expose the computer hardware.

In some examples, a right rack latch may include a rigid right rack lock latch and one or more right spring standoffs that couple the right rack lock latch to the right wall of the chassis. In these examples, the right rack lock latch may include a protrusion dimensioned to fit an indentation in a right side of the rack to lock the chassis in the rack. Additionally, a right spring standoff may couple a distal end of the right rack lock latch to the right wall of the chassis such that a tension of a compression spring maintains a locked position of the right rack lock latch during the shock event.

Similarly, in one embodiment, a left rack latch may include a rigid left rack lock latch and one or more left spring standoffs that couples the left rack lock latch to the left wall of the chassis. In this embodiment, the left rack lock latch may include a protrusion dimensioned to fit an indentation in a left side of the rack to lock the chassis in the rack. Furthermore, a left spring standoff may couple a distal end of the left rack lock latch to the left wall of the chassis such that a tension of a compression spring maintains a locked position of the left rack lock latch during the shock event.

In addition to the various systems and apparatuses described herein, the instant disclosure presents exemplary methods for resisting shock to a data-center rack. For example, a corresponding method may include coupling a distal end of a rigid rack lock latch to a chassis. The method may also include dimensioning a protrusion of the rack lock latch to lock the chassis in a rack. In addition, the method may include dimensioning a spring standoff to couple the distal end of the rack lock latch to the chassis such that a tension maintains a locked position of the rack lock latch during a shock event.

In some examples, coupling the distal end of the rack lock latch to the chassis may include coupling the distal end of the rack lock latch to a wall of the chassis such that the rack lock latch exerts a force outward toward the rack. In one example, dimensioning the protrusion of the rack lock latch may include dimensioning the protrusion to fit an indentation in a side of the rack to lock the chassis in a position. In a further example, the spring standoff of the above method may be dimensioned to include a bar, an anchor coupled to a distal end of the bar, a cap coupled to a proximal end of the bar, a spacer fitted around the bar, and a compression spring dimensioned to maintain the tension separating the cap and the spacer.

Features from any of the above-mentioned embodiments may be used in combination with one another in accordance with the general principles described herein. These and other embodiments, features, and advantages will be more fully understood upon reading the following detailed description in conjunction with the accompanying drawings and claims.

### BRIEF DESCRIPTION OF THE DRAWINGS

The accompanying drawings illustrate a number of exemplary embodiments and are a part of the specification. Together with the following description, these drawings demonstrate and explain various principles of the instant disclosure.

FIG. 1 is a perspective view of a rigid rack lock latch for securing a chassis to a data-center rack.

FIG. 2 is a perspective view of a spring standoff in an uncompressed state.

FIG. 3 is a perspective view of a spring standoff in a compressed state.

FIG. 4 is a top view of a rack latch apparatus in a locked position when coupled to a chassis by spring standoffs.

FIG. 5 is a top view of a rack latch apparatus in an unlocked position when coupled to a chassis by spring standoffs.

FIG. 6 is a perspective view of a chassis secured by multiple rack latch apparatuses.

FIG. 7 is a side view of a drawer dimensioned to slide out from a chassis secured by rack latch apparatuses.

FIG. 8 is a perspective view of a data-center rack system that houses multiple chassis.

FIG. 9 is a flow diagram of an exemplary method for resisting shock to a data-center rack.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the instant disclosure covers all modifications, equivalents, and alternatives falling within the scope of the appended claims.

### DETAILED DESCRIPTION OF EXEMPLARY EMBODIMENTS

The present disclosure describes and illustrates various apparatuses, systems, and methods for resisting shock to a data-center rack. As will be explained in greater detail below, embodiments of the instant disclosure may improve the ability of data-center racks to house computing equipment by ensuring the equipment is secured in place. The disclosed rack latches may improve the realignment of chassis in data-center racks by exerting a force against the chassis to maintain a position in relation to the racks. For example, a spring standoff may return a rack latch to a locked position after a shock dislodges the chassis. The rack latch may then force the chassis back to its position in the rack. Additionally, the rack latch may be specifically designed to fit a groove or indentation in the rack to lock the chassis. Thus, the embodiments described herein may resist displacement of components in a data-center rack.

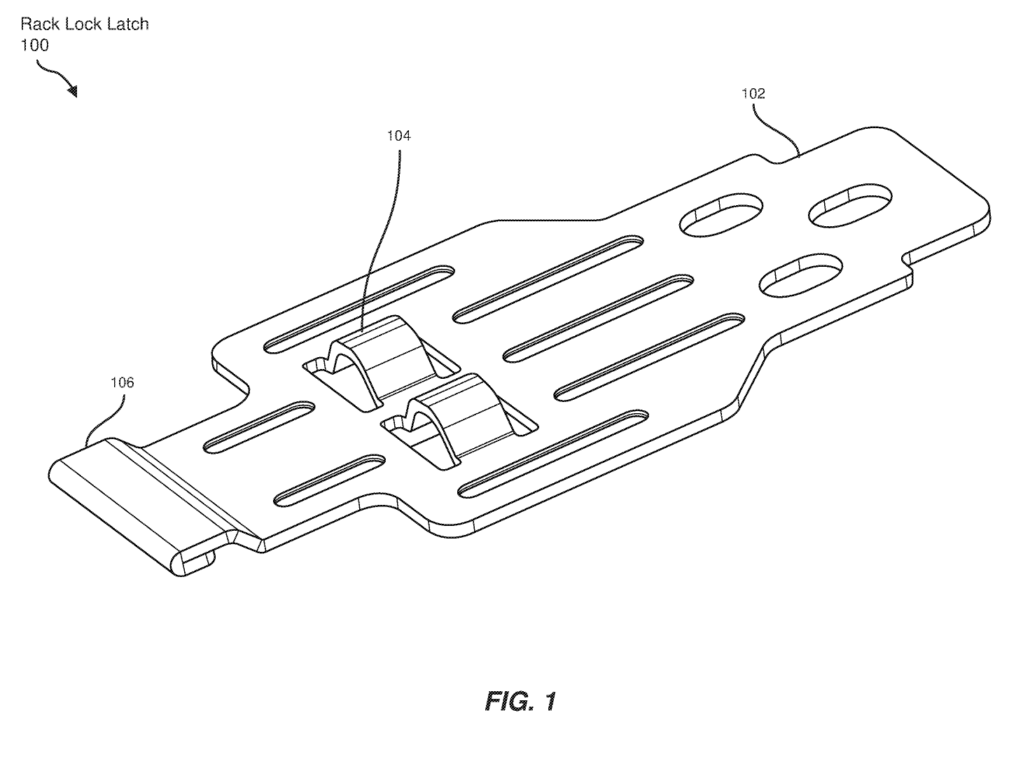

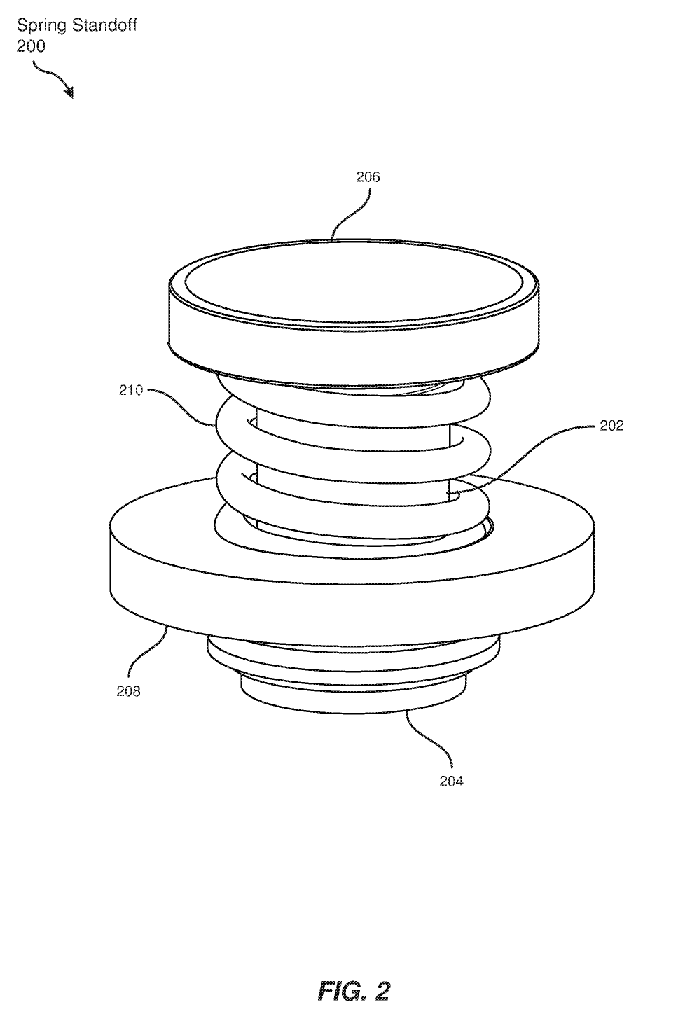

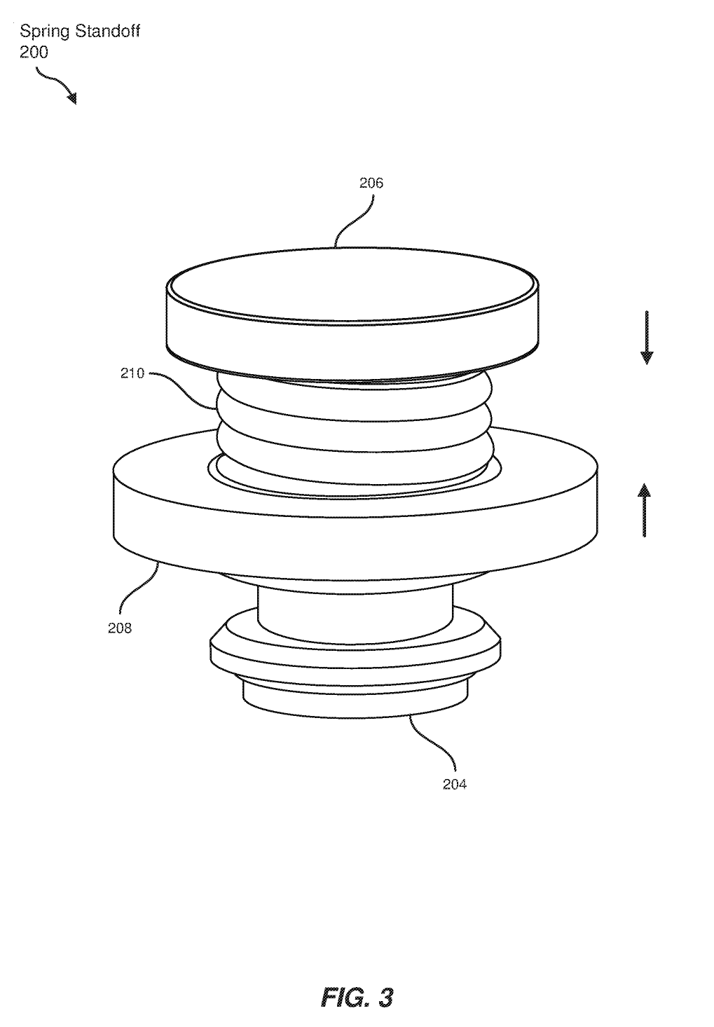

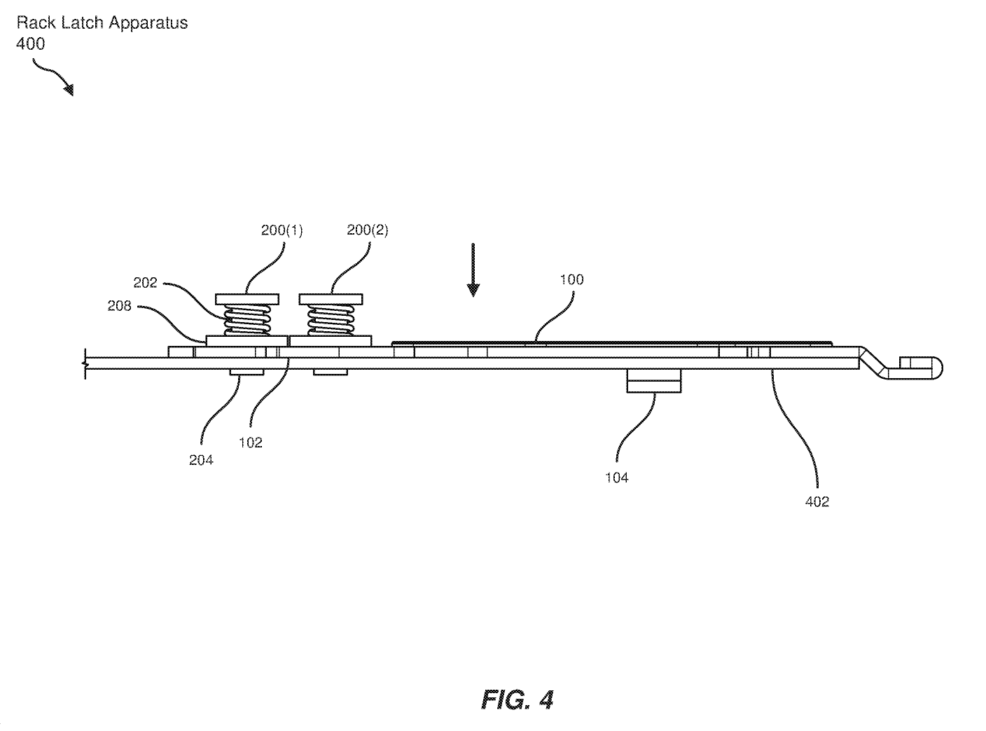

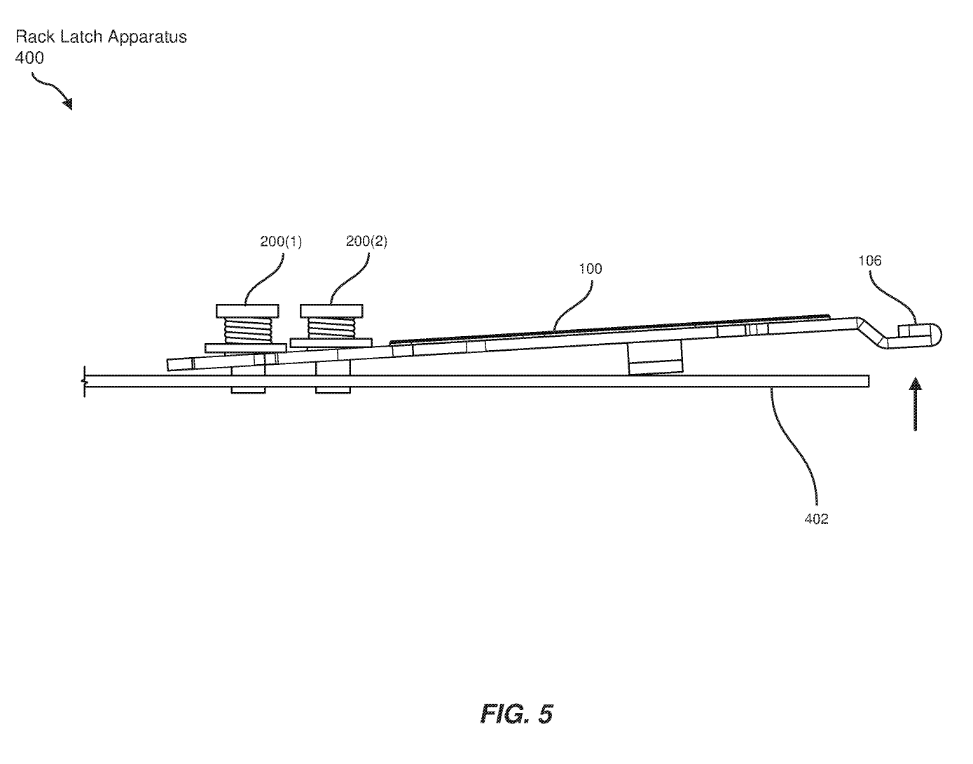

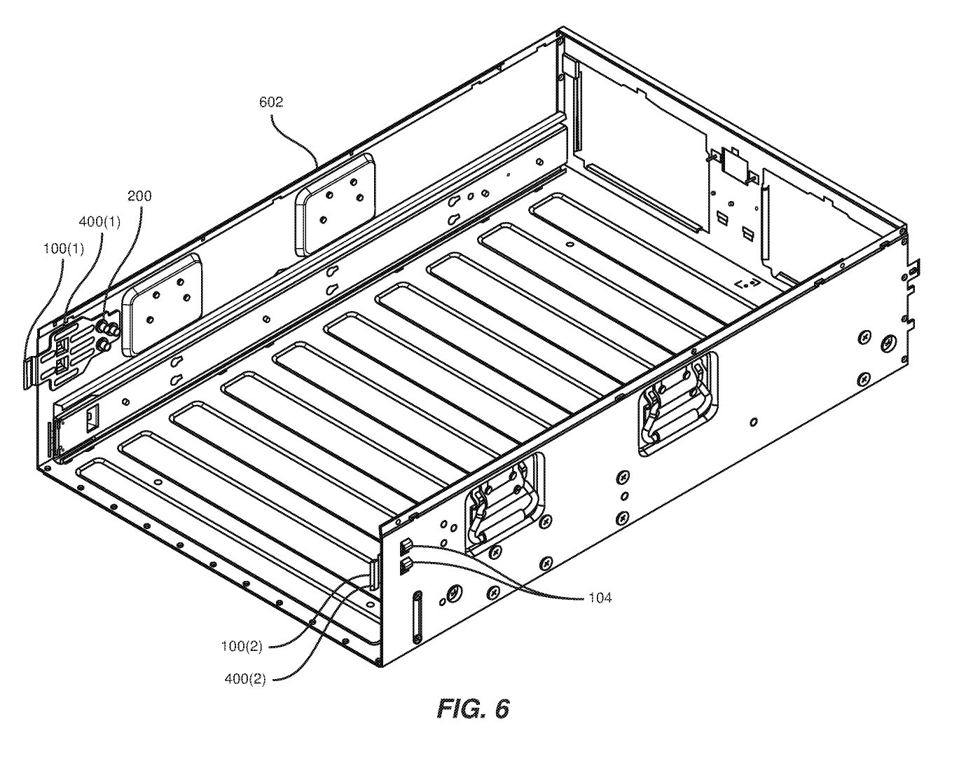

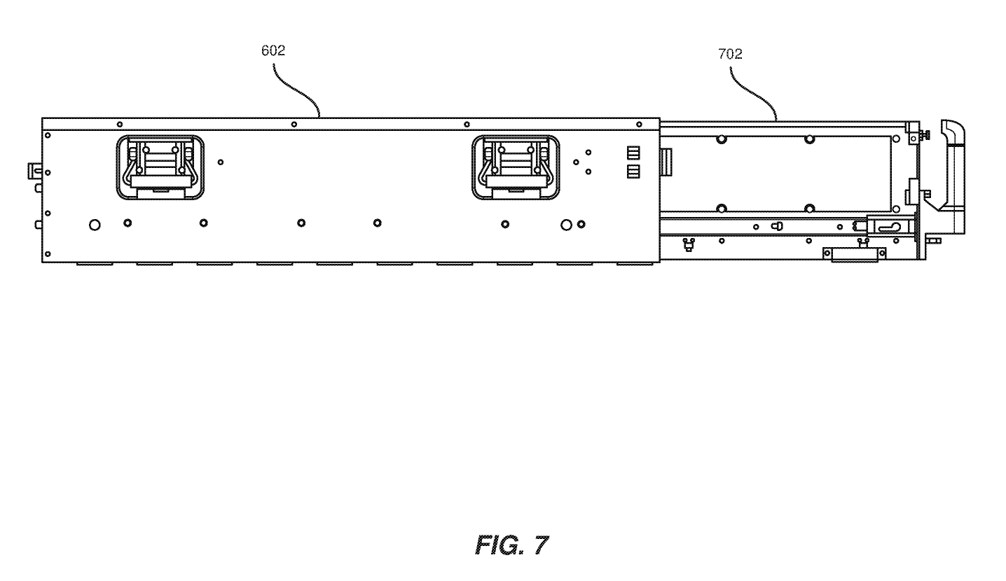

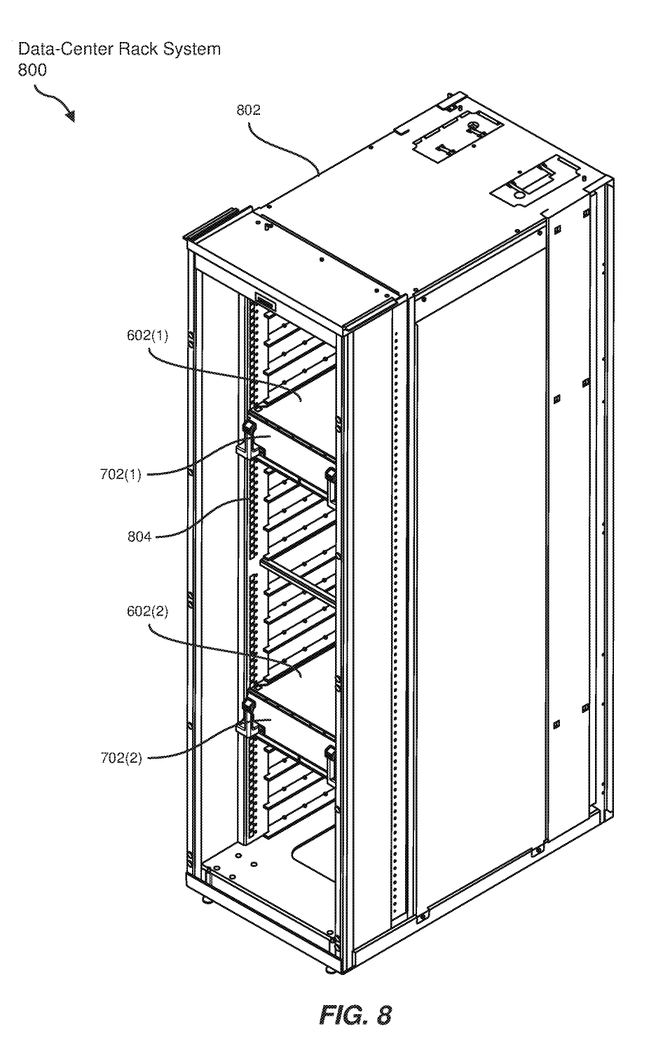

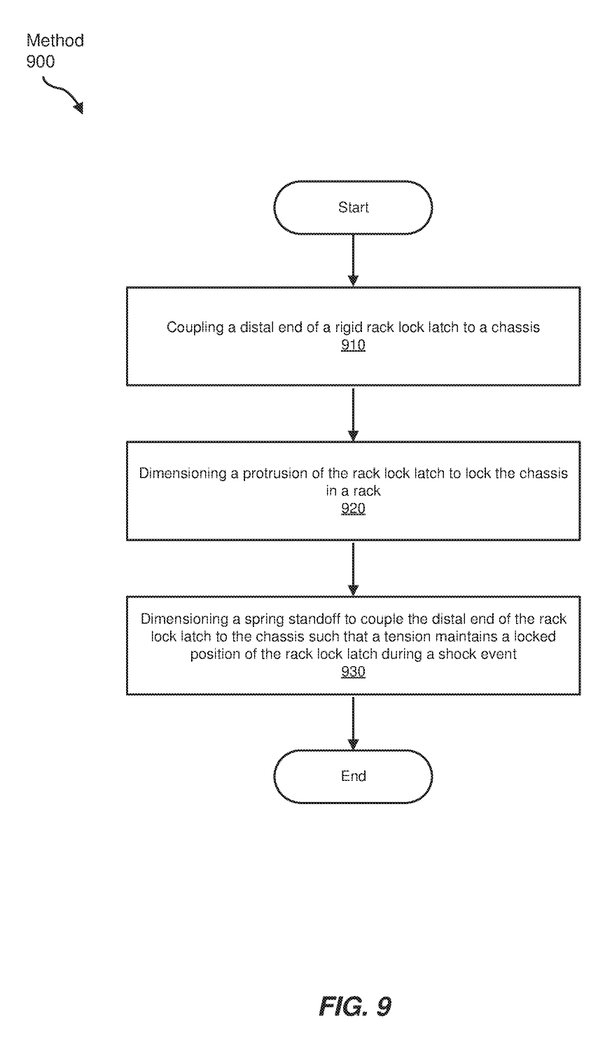

The following will provide, with reference to FIG. 1, detailed descriptions of a rack lock latch for locking a chassis to a rack. In addition, the discussion associated with FIGS. 2-3 will provide detailed descriptions of a spring standoff used to attach the rack lock latch to the chassis. The discussion associated with FIGS. 4-5 will provide examples of a rack latch apparatus coupled to the chassis in locked and unlocked positions. Additionally, the discussion corresponding to FIG. 6 will provide an example of a chassis that utilizes rack latch apparatuses to resist a shock event. Furthermore, the discussion associated with FIGS. 7-8 will provide examples of a data-center rack system that incorporates the chassis to hold a drawer of computing hardware. Finally, the discussion corresponding to FIG. 9 will provide example methods for manufacturing, assembling, configuring, and/or using the rack latch apparatuses presented herein.

The term “chassis,” as used herein, generally refers to a base structure or framework that fits into a rack, such as in a drawer-like fashion, to house or support computing equipment. The term “rack,” as used herein, generally refers to a physical framework designed to house electronic and/or computing equipment, such as servers and/or storage media. As used herein, the term “shock event” generally refers to an instance in which a force is unexpectedly applied to an object, such as a data-center rack and/or components within the rack.

FIG. 1 illustrates a perspective view of a rigid rack lock latch 100 for securing a chassis to a data-center rack. As used herein, the term “rigid” generally refers to a property of inflexibility that prevents an object from bending and/or distorting. For example, rack lock latch 100 may be shaped from an inflexible material, such as solid steel, rather than a flexible material, such as spring steel.

In some examples, rack lock latch 100 may include a distal end 102 coupled to the chassis. In these example, rack lock latch 100 may also include a protrusion 104 dimensioned to lock the chassis in the rack. Additionally, rack lock latch 100 may include a proximal end 106 that may be used to unlock rack lock latch 100. In one embodiment, protrusion 104 of FIG. 1 may be dimensioned to fit an indentation in a side of the rack to lock the chassis in a position. In the example of FIG. 1, protrusion 104 may include two mounds dimensioned to fit in two separate indentations of a rack.

FIG. 2 illustrates a perspective view of a spring standoff 200 in an uncompressed state. In some embodiments, spring standoff 200 may couple rack lock latch 100 of FIG. 1 to the chassis. In one embodiment, spring standoff 200 may include a bar 202, an anchor 204 coupled to a distal end of bar 202, and a cap 206 coupled to a proximal end of bar 202. Although illustrated as a solid bar in FIG. 2, bar 202 may alternatively represent a screw or another form of cylindrical mechanism.

In the above embodiment, spring standoff 200 may also include a spacer 208 fitted around bar 202 to apply a force to rack lock latch 100 of FIG. 1. Additionally, spring standoff 200 may include a compression spring 210 that is dimensioned to maintain the tension separating cap 206 and spacer 208. The term “compression spring,” as used herein, generally refers to a coil that resists compression and exerts an opposite force or tension to maintain an original shape.

In the example of FIG. 2, spring standoff 200 may compress compression spring 210 by applying inward force from both anchor 204 and cap 206. Compression spring 210 may then exert an outward force to resist the applied force.

FIG. 3 illustrates a perspective view of spring standoff 200 in a compressed state. In one example, a force applied to rack lock latch 100 of FIG. 1 may exert a force on spring standoff 200 to compress compression spring 210. For example, the force on rack lock latch 100 may push spacer 208 closer to cap 206, which may then compress compression spring 210 between spacer 208 and cap 206.

FIG. 4 illustrates a top view of a rack latch apparatus 400 in a locked position when coupled to a chassis by spring standoffs 200(1) and 200(2). In one embodiment, rack latch apparatus 400 may include rack lock latch 100 with distal end 102 coupled to a wall 402 of the chassis such that rack lock latch 100 exerts a force outward toward the rack. In this embodiment, spring standoffs 200(1) and 200(2) may couple distal end 102 of rack lock latch 100 to the chassis such that a tension maintains a locked position of rack lock latch 100 during a shock event. The locked position of rack lock latch 100 may be maintained by protrusion 104.

In some examples, the bars of spring standoffs 200(1) and/or 200(2), such as bar 202, may be inserted through wall 402 of the chassis and distal end 102 of rack lock latch 100 such that wall 402 separates anchor 204 and rack lock latch 100. Furthermore, in one example, spacer 208 may exert a force on rack lock latch 100 toward wall 402 of the chassis. The force may push rack lock latch 100 to the locked position as protrusion 104 passes through an aperture in wall 402 of the chassis to lock to the rack.

FIG. 5 illustrates a top view of rack latch apparatus 400 in an unlocked position when coupled to the chassis. In some embodiments, proximal end 106 of rack lock latch 100 may extend beyond the chassis such that a force applied horizontally to proximal end 106 of rack lock latch 100 unlocks rack lock latch 100. In these embodiments, the force applied horizontally to proximal end 106 of rack lock latch 100 may compress spring standoffs 200(1) and/or 200(2). As shown in FIG. 5, the force on rack lock latch 100 may be applied in a direction away from wall 402 of the chassis and, therefore, away from the rack. Additionally, the force on rack lock latch 100 may exceed the tension provided by spring standoffs 200(1) and 200(2). A force less than the tension of spring standoffs 200(1) and 200(2) may result in rack latch apparatus 400 remaining in the locked position of FIG. 4. Thus, spring standoffs 200(1) and 200(2) may be dimensioned to resist a force equal to the force of a shock event but less than an intentional force used to remove the chassis from the rack.

FIG. 6 illustrates a perspective view of a chassis 602 secured by rack latch apparatuses 400(1) and 400(2). In some examples, chassis 602 may include one or more right rack latches, such as right rack latch apparatus 400(2), coupled to a right wall of chassis 602 to maintain a position of chassis 602 in the rack during a shock event. Additionally, chassis 602 may include one or more left rack latches, such as left rack latch apparatus 400(1), coupled to a left wall of chassis 602 to maintain the position of chassis 602. Although positioned on the inside of the walls of chassis 602 in FIG. 6, rack latch apparatuses 400(1) and/or 400(2) could be dimensioned to reside on the outside, at the top, and/or at the bottom of chassis 602 to lock in a position in the rack.

In some embodiments, right rack latch apparatus 400(2) may include a rigid right rack lock latch 100(2) and one or more right spring standoffs that couples right rack lock latch 100(2) to the right wall of chassis 602. Similarly, left rack latch apparatus 400(1) may include a rigid left rack lock latch 100(1) and one or more left spring standoffs, such as left spring standoff 200, that couples left rack lock latch 100(1) to the left wall of chassis 602.

In one example, right rack lock latch 100(2) may include a protrusion, such as protrusion 104, that fits an indentation in a right side of the rack to lock chassis 602 in the rack. Left rack lock latch 100(1) may include a similar protrusion dimensioned to fit an indentation in a left side of the rack.

In some examples, the right spring standoffs may couple a distal end of right rack lock latch 100(2) to the right wall of chassis 602 such that a tension of a compression spring maintains a locked position of right rack lock latch 100(2) during the shock event. Simultaneously or separately, left spring standoff 200 may couple a distal end of left rack lock latch 100(1) to the left wall of chassis 602 such that a tension of a compression spring maintains a locked position of left rack lock latch 100(1) during the shock event.

FIG. 7 illustrates a side view of a drawer 702 dimensioned to slide out from chassis 602 secured by rack latch apparatuses. In this example, chassis 602 may be dimensioned to hold drawer 702. In some examples, drawer 702 may be dimensioned to slide in chassis 602 such that drawer 702 extends away from the rack to expose computer hardware housed by drawer 702.

FIG. 8 illustrates a perspective view of a data-center rack system 800 that houses chassis 602(1) and 602(2). In one embodiment, data-center rack system 800 may include a rack 802 dimensioned to hold computer hardware. In addition, data-center rack system 800 may include one or more chassis, such as chassis 602(1) and 602(2), coupled to rack 802 and dimensioned to hold drawers 702(1) and 702(2), respectively. In this embodiment, data-center rack system 800 may also include one or more rack latches, such as rack latch apparatuses 400(1) and 400(2) of FIG. 6, coupled to walls of the chassis to maintain a position of the chassis in rack 802 during a shock event. Furthermore, in this embodiment, drawers 702(1) and/or 702(2) may be dimensioned to slide in chassis 602(1) and/or 602(2) such that drawers 702(1) and/or 702(2) extend away from rack 802 to expose the computer hardware.

In some examples, the rack lock latches of chassis 602(1) and/or 602(2) may include protrusions, such as protrusion 104 of FIG. 1, that are dimensioned to fit indentations in a side of rack 802. In the example of FIG. 8, the protrusions ay be dimensioned to fit an indentation 804 in rack 802 to lock chassis 602(1) and 602(2) in rack 802. Rack 802 may contain a plurality of indentations, including indentation 804, such that chassis 602(1) and/or 602(2) may be installed in different locations and lock to indentations at the locations. For example, as illustrated in FIG. 8, rack 802 may include a vertical column of indentations on one side. Additionally or alternatively, rack 802 may include a similar column of indentations on the other side.

In one embodiment, during a shock event, chassis 602(1) and/or 602(2) may shift out of alignment from rack 802. In response, a spring standoff, such as spring standoff 200 of FIG. 2, may couple a rack lock latch, such as rack lock latch 100 of FIG. 1, to chassis 602(1) and/or 602(2) such that a tension maintains the locked position of the rack lock latch, which may maintain the positions of chassis 602(1) and/or 602(2). Alternatively, the spring standoff may exert a force on the rack lock latch to return chassis 602(1) and/or 602(2) to the locked position in rack 802. For example, protrusion 104 of FIG. 1 may be sloped such that the force on rack lock latch 100 slowly eases rack lock latch 100 back into position against chassis 602(1) and/or 602(2) as the slope slides into indentation 804 of rack 802.

FIG. 9 shows an example method for manufacturing, assembling, using, adjusting, or otherwise configuring or creating the systems and apparatuses presented herein. The steps shown in FIG. 9 may be performed by any individual and/or by any suitable type or form of manual and/or automated apparatus. In particular, FIG. 9 illustrates a flow diagram of an exemplary method 900 for assembling a rack latch apparatus.

As shown in FIG. 9, at step 910, a distal end of a rigid rack lock latch may be coupled to a chassis. For example, as shown in FIG. 4, distal end 102 of rack lock latch 100 may be coupled to a chassis. In this example, distal end 102 of rack lock latch 100 may be coupled to the chassis by coupling distal end 102 of rack lock latch 100 to wall 402 of the chassis such that rack lock latch 100 exerts a force outward toward the rack. Furthermore, in this example, the rack may surround the chassis and a side of the rack may be positioned adjacent to wall 402 of the chassis.

At step 920, a protrusion of the rack lock latch may be dimensioned to lock the chassis in the rack. For example, as illustrated in FIG. 4 and FIG. 8, protrusion 104 of rack lock latch 100 may be dimensioned to lock chassis 602(1) and/or 602(2) in rack 802. In this example, protrusion 104 of rack lock latch 100 may be dimensioned to fit indentation 804 in the side of rack 802 to lock chassis 602(1) and/or 602(2) in position.

At step 930, a spring standoff may be dimensioned to couple the distal end of the rack lock latch to the chassis such that a tension maintains a locked position of the rack lock latch during a shock event. For example, as shown in FIG. 4, spring standoff 200 may be dimensioned to couple distal end 102 of rack lock latch 100 to the chassis, such as chassis 602 of FIG. 6, such that the tension of spring standoff 200 maintains the locked position of rack lock latch 100 during the shock event. In the example of FIG. 2, spring standoff 200 may be dimensioned to include bar 202, anchor 204 coupled to a distal end of bar 202, cap 206 coupled to a proximal end of bar 202, spacer 208 fitted around bar 202, and compression spring 210 dimensioned to maintain the tension separating cap 206 and spacer 208.

In the above example, spring standoff 200 may be coupled to rack lock latch 100 and chassis 602 by mooring anchor 204 at wall 402 of chassis 602 and passing bar 202 through chassis 602 and rack lock latch 100. Spacer 208 may then be fitted around bar 202 to exert a force against rack lock latch 100. Compression spring 210 may also be fitted around bar 202 to provide the force, and cap 206 may be coupled to the proximal end of bar 202 to confine compression spring 210 and maintain the tension.

As discussed throughout the instant disclosure, the disclosed methods, systems, and apparatuses may provide one or more advantages over traditional methods of resisting shocks to a data-center rack. For example, the rack latch apparatuses described herein may prevent movement of hardware components in a chassis from small shocks to a rack. As another example, by configuring a spring standoff to exert a tension on a rigid latch against the chassis, the systems described herein may force the chassis back into position in the event of dislodging due to a strong shock. Additionally, the disclosed chassis may contain a drawer dimensioned to hold and/or protect various hardware. Furthermore, the rack latch apparatuses described herein may enable the chassis to be easily removed and/or installed in racks by dimensioning protrusions to lock into the racks. Thus, the mechanisms disclosed herein may improve methods to secure and reposition hardware in data-center racks during shock events.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the instant disclosure. The embodiments disclosed herein should be considered in all respects illustrative and not restrictive. Reference should be made to the appended claims and their equivalents in determining the scope of the instant disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A rack latch apparatus comprising:
a rigid rack lock latch comprising:
a distal end coupled to a chassis; and
a protrusion dimensioned to lock the chassis in a rack; and
at least one spring standoff that couples the distal end of the rack lock latch to the chassis such that a tension maintains a locked position of the rack lock latch during a shock event.

2. The rack latch apparatus of claim 1, wherein the distal end of the rack lock latch is coupled to a wall of the chassis such that the rack lock latch exerts a force outward toward the rack.

3. The rack latch apparatus of claim 1, wherein the protrusion is dimensioned to fit an indentation in a side of the rack to lock the chassis in a position.

4. The rack latch apparatus of claim 1, wherein a proximal end of the rack lock latch extends beyond the chassis such that a force applied horizontally to the proximal end of the rack lock latch unlocks the rack lock latch.

5. The rack latch apparatus of claim 4, wherein the force applied horizontally to the proximal end of the rack lock latch compresses the spring standoff.

6. The rack latch apparatus of claim 1, wherein the spring standoff comprises:
a bar;
an anchor coupled to a distal end of the bar;
a cap coupled to a proximal end of the bar;
a spacer fitted around the bar; and
a compression spring dimensioned to maintain the tension separating the cap and the spacer.

7. The rack latch apparatus of claim 6, wherein the bar is inserted through a wall of the chassis and the distal end of the rack lock latch such that the wall of the chassis separates the anchor and the rack lock latch.

8. The rack latch apparatus of claim 7, wherein the spacer exerts a force on the rack lock latch toward the wall of the chassis.

9. A data-center rack system comprising:
a rack dimensioned to hold computer hardware;
at least one chassis coupled to the rack and dimensioned to hold a drawer;
at least one right rack latch coupled to a right wall of the chassis to maintain a position of the chassis in the rack during a shock event; and
at least one left rack latch coupled to a left wall of the chassis to maintain the position of the chassis in the rack during the shock event.

10. The data-center rack system of claim 9, wherein the drawer is dimensioned to slide in the chassis such that the drawer extends away from the rack to expose the computer hardware.

11. The data-center rack system of claim 9, wherein the right rack latch comprises:
a rigid right rack lock latch; and
at least one right spring standoff that couples the right rack lock latch to the right wall of the chassis.

12. The data-center rack system of claim 11, wherein the right rack lock latch comprises a protrusion dimensioned to fit an indentation in a right side of the rack to lock the chassis in the rack.

13. The data-center rack system of claim 11, wherein the right spring standoff couples a distal end of the right rack lock latch to the right wall of the chassis such that a tension of a compression spring maintains a locked position of the right rack lock latch during the shock event.

14. The data-center rack system of claim 9, wherein the left rack latch comprises:
a rigid left rack lock latch; and
at least one left spring standoff that couples the left rack lock latch to the left wall of the chassis.

15. The data-center rack system of claim 14, wherein the left rack lock latch comprises a protrusion dimensioned to fit an indentation in a left side of the rack to lock the chassis in the rack.

16. The data-center rack system of claim 14, wherein the left spring standoff couples a distal end of the left rack lock latch to the left wall of the chassis such that a tension of a compression spring maintains a locked position of the left rack lock latch during the shock event.

17. A method comprising:
coupling a distal end of a rigid rack lock latch to a chassis;
dimensioning a protrusion of the rack lock latch to lock the chassis in a rack; and
dimensioning a spring standoff to couple the distal end of the rack lock latch to the chassis such that a tension maintains a locked position of the rack lock latch during a shock event.

18. The method of claim 17, wherein coupling the distal end of the rack lock latch to the chassis comprises coupling the distal end of the rack lock latch to a wall of the chassis such that the rack lock latch exerts a force outward toward the rack.

19. The method of claim 17, wherein dimensioning the protrusion of the rack lock latch comprises dimensioning the protrusion to fit an indentation in a side of the rack to lock the chassis in a position.

20. The method of claim 17, wherein the spring standoff comprises:
a bar;
an anchor coupled to a distal end of the bar;
a cap coupled to a proximal end of the bar;
a spacer fitted around the bar; and
a compression spring dimensioned to maintain the tension separating the cap and the spacer.
